(19) United States
(12) Patent Application Publication
(10) Pub. No.: US 2026/0327912 A1
(43) Pub. Date: Oct. 22, 2026

(54) MULTILAYER METALLIZED PAPER-BASED PACKAGING MATERIAL

(71) Applicant: Société des Produits Nestlé S.A., Vevey (CH)

(72) Inventors: Abhijit Bhattacharya, Epalinges (CH); Jenni Irina Jukarainen, Pully (CH)

(73) Assignee: Société des Produits Nestlé S.A., Vevey (CH)

(21) Appl. No.: 19/119,538

(22) PCT Filed: Oct. 20, 2023
(86) PCT No.: PCT/EP2023/079215

§ 371 Date: Apr. 9, 2025

(30) Foreign Application Priority Data
Oct. 24, 2022 (EP) 22203403.5

(51) Int. Cl. D21H 21/14; B65D 65/42; C23C 14/20; C23C 14/24; D21H 19/08; D21H 19/10; D21H 19/82; D21H 19/84; D21H 27/10

(52) U.S. Cl. CPC D21H 21/14; B65D 65/42; C23C 14/20; C23C 14/24; D21H 19/08; D21H 19/10; D21H 19/82; D21H 19/84; D21H 27/10

(57) ABSTRACT

A multi-layer metallized paper-based packaging material includes, from its outer side to its inner side: a paper layer, at least one organic barrier layer, at least one inorganic barrier layer, and at least one organic heat seal layer. The paper layer has a grammage in the range of 30 to 120 g/m². The organic barrier layer is of a polymer selected from polyvinylalcohol (PVOH), ethylene vinyl alcohol (EVOH), butenediol vinyl alcohol co-polymer (BVOH), or a combination thereof, in an amount of 0.5 to 20 g/m². The inorganic barrier layer is selected from metals, metalloids, or a combination thereof, and has a thickness between 1 and 100 nm. The organic heat seal layer is made of an acrylic or methacrylic acid polymer grafted with at least one type of ionomer, and is applied in an amount between 2 and 20 g/m².

### FIELD OF THE INVENTION

The present invention relates to a multi-layer paper-based packaging material comprising a paper layer, an ultrathin metal or metalloid layer for water vapour barrier that is sandwiched between ultrathin coating layers that provide oxygen barrier and sealability to the structure.

### BACKGROUND OF THE INVENTION

Plastic packaging is used frequently in the economy and in people's daily lives. It has multiple advantages, such as its flexibility and its light weight. Such a weight reduction contributes to fuel saving and CO₂ reduction during transport, for example. Its barrier properties help to reduce food waste due a positive effect on increasing shelf life. The barrier properties also help to secure food safety.

However, with increasing environmental awareness, and in order to ensure that plastic waste is reduced, multilayer packaging materials have been developed which include a paper or cardboard layer, and one or several layers of plastic or metal films, which provide robustness as well as barrier properties, especially to oxygen and moisture.

In the most recent years, environmental awareness increased even further, in particular in relation to waste materials, for instance used packages, that are not recycled or treated properly. This challenge is considered very seriously by industrials who spend increasingly extensive efforts to develop new packaging materials that are rapidly and easily recyclable.

When manufacturing multilayer packaging material structures today, applying a layer of plastic by known techniques, in particular extrusion (extrusion-lamination), or similarly by an adhesive lamination process, necessarily provides a high thickness of the plastic film thus obtained onto the paper.

Even for relatively low thicknesses of extruded or laminated polymers in multilayer structures as described above, the cohesive strength of the polymer film is very high and the level of adhesion of the polymer to the paper or cardboard (i.e. cellulosic) substrate is also high. This prevents such polymer to detach from the substrate when recycled and prevents recycling and repulping of the cellulosic fiber portion in a paper-stream recycling process.

Therefore, later during the recycling process, the multilayer structure comprising a mixture of paper and plastic (polymer) films either extruded (by classic techniques as extrusion-lamination or extrusion coating) or adhesive-laminated, has limited recyclability in standard paper-stream recycling process because the plastic layer is too thick to be dispersed and at the same time the same layer has cohesion strength and adhesion level to the adjacent layers of the structure, which are way too high to be separated from the other layers of materials, especially from the paper fibres. The extruded plastic film remains intact within the paper pulp bath, hence making it difficult to recycle paper pulp from the repulping process.

More than that, the recycling process of known laminated materials described above is expensive, and energy consuming and characterized with relatively low yield of paper fibres that are recycled (below 80% from the total amount of packaging materials in the entire structure), hence, not sufficiently environmentally friendly from a disposal and recycling perspective. There is also room for improving the recyclability of the rest of the packaging material (i.e. the plastic polymer and the metal parts, e.g. aluminium parts) in a paper recycling stream.

Furthermore, for packaging intended for food products, good barrier properties are essential for maintaining the safety and quality of packaged foods. Typically, such barrier properties include gas barrier, for example to oxygen and water vapor (moisture), and if possible, also, liquid tightness.

One way to provide good moisture barrier in paper-based packaging materials, is the introduction of a metal or metalloid layer in a so-called “metallized” layer. In the present description, the word “metallized” (for instance in the expression “metallized barrier paper layer”) is meant to encompass the deposition at the surface of paper or paperboard, of metal or metalloid atoms. One can even consider embodiments comprising the deposition of an alloy of metal and metalloid. Metalloids are close to metals in some of their characteristics. Aluminium oxide and silicon oxide are examples of metalloids.

Problematic with the introduction of a metal layer in paper-based packaging material is the sensitivity of the metal layer to mechanical stress as well as poor adhesion of metal to paper surface, poor smoothness and high porosity of paper materials. Mechanical stress can—for example—easily result in a loss of the required barrier properties that the metallized packaging material should provide. This may be due to the processing of the multilayer material during manufacturing of package using for example a form-fill-seal packaging machine, whereby said material is stretched, bent, rolled, compressed and/or heated during forming and sealing of packages by conventional packaging forming methods. Such packaging manufacturing processes cause high mechanical and or chemical stress to the material and in particular to the ultrathin metallized layer of metal or metalloid, and therefore leads to damaging such layers, creating cracks and tears which are in most cases irreversible.

Having considered the above, there is a need for a multi-layer metallized paper-based packaging material that exhibits simultaneously:
sufficient barrier properties, in particular to oxygen and moisture,
a high resilience to mechanical stress, such that it keeps the same level of barrier even when subjected to transformation processes such as the ones used for manufacturing packages,
a greatly reduced amount of plastic polymer contents compared to the content of cellulosic material,
and also preferably recyclability in the paper stream and/or biodegradability in diverse environmental conditions especially (but not only) in a marine environment.

### SUMMARY OF THE INVENTION

The objective of the present invention is achieved with a multi-layer metallized paper-based packaging material comprising, from its outer side to its inner side:
a paper layer having a grammage comprised in the range of 30 to 120 g/m²,
at least one organic barrier layer of a polymer selected within the list of: polyvinylalcohol (PVOH), ethylene vinyl alcohol (EVOH), butenediol vinyl alcohol co-polymer (BVOH), or a combination thereof, in an amount of 0.5 to 20 g/m², preferably in an amount of 1 to 10 g/m², more preferably in an amount of 2 to 8 g/m²,
at least one inorganic barrier layer selected within the list of: metals, metalloids, or a combination thereof, said inorganic layer having a thickness comprised between 1 and 100 nm, and
at least one organic heat seal layer made of an acrylic or methacrylic acid polymer grafted with at least one type of ionomer, said heat seal layer being applied in an amount comprised between 2 and 20 g/m², preferably in an amount comprised between 4 and 9 g/m².

The overall thickness of polymer coating layers in the structure is extremely reduced compared to the thickness of paper material, therefore the inventors have achieved to overcome the technical limitations of the known multilayer barrier structures, and achieve a packaging multilayer structure with excellent barrier properties against oxygen and moisture transfer, as well as resistance to liquid contact from their inner or outer surfaces, while achieving a total contents of cellulosic fibres comprised preferably up to 85% or even 95% of the overall material weight.

Furthermore, pre-coating polymer layer being water soluble promotes recyclability. The fact that the inventors succeeded in forming a multilayer structure completely deprived of polymer layers formed by extrusion lamination and/or adhesive lamination, provides a multilayer structure with a ratio of cellulosic fibre to non-cellulosic material, which is extremely high in fibre contents, and wherein the polymer layers are easy to disintegrate in repulping process due to the solubility of precoating layer in water, and also relatively high adhesion of the post-metallization (or post-metalloidization) polymer to the metallized layer inhibits fragmentation of the metal layer during repulping which results in cleaner fibres from the repulping process. The resulting structure therefore demonstrates excellent repulping capabilities and high fibre yield of good quality which allows it to be accepted in standard recycled paper mills in most countries. The very low content of non-cellulosic polymer and vacuum-deposited metal materials, makes the whole material of the invention easily disintegrated, dissolved and separated during recycling processes designed for cellulosic materials like paper or cardboard, unlike existing multi-layer barrier structures known from the art.

The particular improvement brought by the present invention over the existing barrier paper materials is the incorporation into said multilayer barrier packaging paper of a heat seal layer comprising an acrylic or methacrylic acid polymer that is grafted with a ionomer.

The inventors have surprisingly found that by grafting an acrylic or methacrylic acid polymer with a ionomer, the heat seal innermost coating is improved in at least two different manners.

First, the heat seal layer made from such an acrylic or methacrylic acid-ionomer material, achieves excellent resistance to mechanical stress (in particular to bending, stretching, and shearing forces applied to the material during manufacturing of a package therefrom). This mechanical resistance protects the whole structure, and especially the adjacent inorganic layer, against damages, and more particularly against irreversible cracking.

Second, grafting the acrylic or methacrylic acid polymer with a ionomer was found to modify the molecular set-up of the material: molecules of acrylic or methacrylic acid-ionomer form a matrix of molecules over the surface of the coating made therefrom, such that the heat seal layer demonstrates high hot tack characteristics which yields superior seal integrity of formed and filled packages and eventually enabling barrier retention in the final package.

Advantageously, the organic heat seal material is a methacrylic acid polymer chemically modified (i.e. grafted) with a ionomer.

In a highly preferred embodiment of the invention, the inorganic layer comprises metals or metalloids selected within the list of: aluminium, aluminium oxide (AlOx), or silicon oxide (SiOx), said metals and/or metalloids being deposited either by vacuum deposition or transfer metallization. In one particularly preferred embodiment, the inorganic layer is vacuum-deposited layer of aluminium.

Furthermore, in a preferred embodiment of the invention, the ionomer grafted to the acrylic or methacrylic acid polymer is a sodium ionomer.

Preferably, the acrylic or methacrylic acid-ionomer polymer has a molecular weight comprised between 85 and 90 g/mol.

Each of the organic layer is preferably deposited to an adjacent layer either by aqueous dispersion, or by aqueous solution deposition.

Advantageously, the organic barrier layer is deposited by aqueous solution deposition, and the organic heat seal layer is deposited by aqueous dispersion coating.

In one embodiment of the invention, the paper layer is covered on its outer surface with an ink layer. The ink layer has a thickness comprised preferably between 0.5 and 5 g/m². Preferably the ink layer is selected within the list of: water-based inks, solvent-less inks, or a combination thereof.

More preferably, the paper layer or the ink layer is covered on its outer surface by an outermost layer of an over-print varnish (OPV). The OPV layer has a grammage comprised preferably between 0.5 and 10 g/m².

The optional OPV layer also participates to the improved resistance of the barrier paper to hygroexpansive strain, especially as it provides improved barrier to moisture (water vapour transmission rate or “WVTR”) under high humidity conditions.

In an advantageous embodiment, the overprint varnish outermost layer is a styrene acrylic varnish.

The multi-layer metallized paper-based packaging material according to the invention advantageously achieves barrier properties against oxygen and moisture as follows: a Water Vapour Transmission Rate (WVTR) below 0.5 g/m²/day (measured at 23 °C, 85% Relative Humidity) and/or an Oxygen Transmission Rate (OTR) below 0.1 cm³/m²/day bar (measured at 23 °C, 50% RH). These values are measured after subjecting the sample to an in-plane tensile pre-straining up to 2% and also after subjecting the samples to a Gelboflex testing apparatus in 3 cycles, according to flexibility testing standard ASTM F392 or equivalent.

The multi-layer metallized paper-based packaging material according to the invention preferably has a strain at break under in-plane tensile loading up to 5% in machine direction and up to 15% in the cross-machine direction of the paper. The strain at break of the total paper structure is 2.5% in machine direction and 9% in cross-direction which results into high mechanical resilience.

The present invention is further directed to a tridimensional closed packaging item made of a multi-layer metallized paper-based packaging material as described before, which is obtained by forming, then filling with an edible product for human or animal consumption, and then sealing said packaging material.

The present invention is further directed to the use of a multi-layer metallized paper-based packaging material described before, for packing an edible product for human or animal consumption.

The present invention is further directed to a packaged edible product, comprising a multi-layer metallized paper-based packaging material per the invention, which is filled with an edible product for food or animal consumption.

Preferably, said edible product is a powder, a gel, or kibbles and is selected within the list of: soluble coffee, nutrition compositions for infant, adult, or elderly consumption, soup, confectionery or candies, chocolate-based products, dry animal food, dairy products.

As used in this specification, the words “comprises”, “comprising”, and similar words, are not to be interpreted in an exclusive or exhaustive sense. In other words, they are intended to mean “including, but not limited to”.

### BRIEF DESCRIPTION OF THE DRAWINGS

Additional features and advantages of the present invention are described in, and will be apparent from, the description of the presently preferred embodiments which are set out below with reference to the drawings in which:

FIG. 1 shows a first embodiment of a multilayer structure according to the invention;

FIG. 2 shows a second embodiment of a multilayer structure according to the invention.

### DETAILED DESCRIPTION OF THE INVENTION

Generally, in the present specification, “extrusion coating”, it is meant a method to provide a layer of polymer by using an extruder which forces melted thermoplastic resin (e.g. polyethylene) through a horizontal slot-die onto a moving web of substrate (e.g. paper). The resulting product is a permanently coated web structure.

By “extrusion lamination”, it is meant a similar process to extrusion coating, whereby a polymer resin is extruded between two substrates (e.g. a layer of paper and another layer of polymeric film), and acts as a bonding agent.

By “adhesive lamination”, it is meant a process whereby one paper material is coated with adhesive and laminated to a second paper or paperboard material. In a lamination process, two thick layers of material are combined, either by extrusive lamination or adhesive lamination, whereby the thickness of each layer is far greater than the thickness obtained by dispersion coating.

By “dispersion coating”, it is meant a coating technique whereby an aqueous dispersion of fine polymer particles or polymer solution is applied to the surface of paper or board as such, in order to form a solid, non-porous film after drying. Dispersion coating can be performed by gravure, flexo-gravure, rod, blade, slot-die, curtain air knife, roll coating or any other known method of paper coating. Dispersion coating can create a much thinner layer than extrusion lamination and/or adhesive lamination, since the polymer is mixed in an aqueous water solution. This brings advantages in terms of quantity of polymer usage, its barrier performance and recyclability of resulting paper structure. The target of dispersion coating is to achieve a barrier layer against water, water vapour, grease, oil, gas, etc. by environmentally friendly coating. Another target is to prepare surface of paper material for a vacuum deposition process.

By “fibre”, it is meant a cellulosic fibre, which is generally extracted from plants, seeds or trees; such fibres contain not only cellulose molecules, but also hemi-cellulose as well as lignin.

The multilayer structure according to the invention is preferably designed to qualify for being as well recyclable in a standard recycled paper stream process, according to most regional or national paper recyclability regulations.

Recyclability in the paper stream is achieved by a multilayer structure according to the invention wherein:
fibre contents is predominant relatively to all the ingredients contained therein (the definition of recyclability in the paper stream depends on national legislations but in average, it is required that the material contains at least 80% fibre to be accepted in a recycling process dedicated to paper), and
the inorganic layer is ultrathin (i.e. a few nanometres, typically between 1 and 100 nm) and its thickness is constituted of a few atoms,
the organic polymer layers are all deposited by aqueous dispersion or aqueous solution deposition coating, which means that the layers thus obtained are sufficiently thin in relation to paper thickness to achieve an extremely high paper contents of the overall structure,, which makes the whole structure compatible with paper recycling processes as explained herein before
the organic barrier layer preferably comprises a polymer which is water soluble (i.e. PVOH, EVOH and/or BVOH), which makes it easier to separate the fiber from the rest of the materials of the structure, in particular from the cellulosic contents.

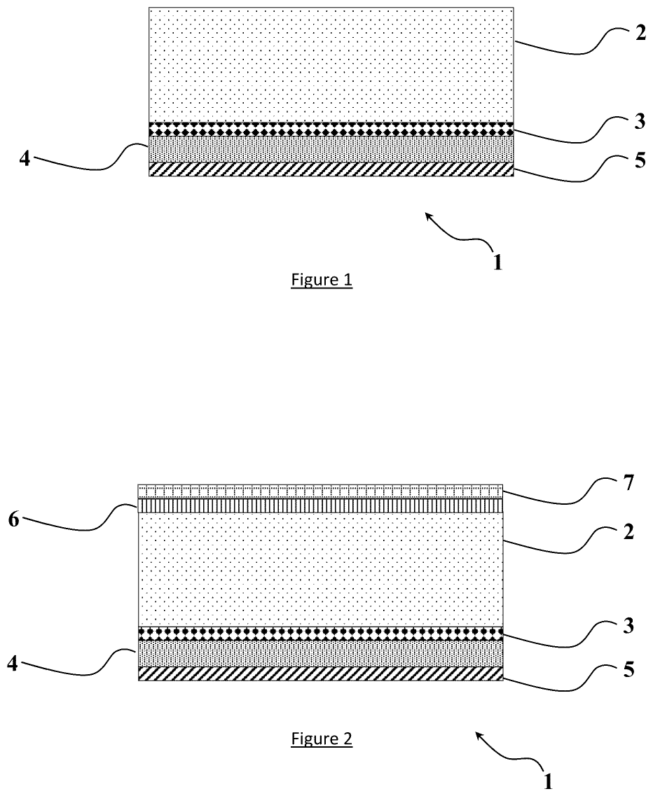

In FIG. 1 is illustrated a first embodiment of the invention. In this embodiment, the multilayer structure 1 comprises in order, from its outer side (i.e. the side of the material which is turned towards the outside of the package made thereof) towards its inner side (i.e. the inner side in contact with the packaged product in a package made thereof):
a highly smooth paper layer 2 of grammage 62 g/m²,
a first organic polyvinyl alcohol-based (PVOH) pre-metallization coating layer 3 that provides mainly gas (especially oxygen) barrier properties and is applied as an aqueous solution in weight of 3 g/m²,
an inorganic vacuum deposited layer 4 of aluminium having a thickness of 40 nm, which provides mainly moisture vapour barrier properties, and
a second organic coating layer 5 of methacrylic acid ionomer-based coating which serves as a heat seal layer and is applied as an aqueous dispersion in weight of 5 g/m².

In this embodiment, the deposition techniques for the first and second organic layers as mentioned above, allow to improve their recyclability in a paper stream process.

The structure 1 of this first embodiment achieves high moisture and gas barrier properties with values of Oxygen Transmission Rate (OTR) below 0.5 cm 3/m²/day measured at 23 °C and 50% relative humidity (RH), and water vapour transmission rate (WVTR) below 0.5 g/m²/day measured at 23 °C and 85% RH.

The strain at break of the total structure 1 is measured 2.5% in machine direction and 9% in cross-direction%. These values provide excellent resilience properties which allow to protect the aluminium layer during processing of the structure in conventional packaging forming processes. No cracking of the aluminium layer is generated during bending, stretching and/or sealing of the material when manufacturing a package out of it, which results in maintaining the level of OTR and WVTR barrier properties equivalent before and after a package is formed from the multilayer structure material.

In FIG. 2, is depicted a structure similar to that described above in relation to FIG. 1.

However, in this second exemplary embodiment of the invention, the outer surface of the paper layer 2 is covered with two layers as follows, in order from the outside face to the inside of the packaging material:
an outermost acrylic based overprint varnish layer 7, which is applied as an aqueous dispersion in weight of 1 g/m²,
a water-based ink 6 applied as an aqueous dispersion in weight of 1 g/m²; this water-based ink layer 6 is located between the outermost overprint varnish layer 7, and the paper layer 2.

The rest of the layers in the structure 1 remain similar to the structure described in reference to FIG. 1, that is to say:
a first organic polyvinyl alcohol-based (PVOH) pre-metallization coating layer 3 that provides mainly gas (esp. oxygen) barrier properties and is applied as an aqueous solution in weight of 3 g/m²,
an inorganic vacuum deposited layer 4 of aluminium having a thickness of 40 nm, which provides mainly moisture vapour barrier properties, and
a second organic coating layer 5 of methacrylic acid ionomer-based coating that is applied as an aqueous dispersion in weight of 5 g/m².

The structures corresponding to the above-described embodiments fulfil the requirements for recyclability of the material or a packaging made thereof, in standard recycled paper mill conditions.

In all of the embodiments of the invention described above, the multilayer structure can comprise other additional and optional layers not described in full details therein. Such layers can comprise for instance a print layer on the outer surface of the paper layer, as well as optionally a protective layer that is deposited on the external side of the print layer, and therefore constitutes the outermost layer of the whole structure. Print and optional protective layers are not described in more detail because they are known technology to the skilled person.

1. A multi-layer metallized paper-based packaging material comprising, from its outer side to its inner side:
a paper layer having a grammage in a range of from 30 to 120 g/m²;
at least one organic barrier layer of a polymer selected from the group consisting of polyvinylalcohol (PVOH), ethylene vinyl alcohol (EVOH), butenediol vinyl alcohol co-polymer (BVOH), and a combination thereof, in an amount of from 0.5 to 20 g/m²;
at least one inorganic barrier layer selected from the group consisting of metals, metalloids, and a combination thereof, the inorganic barrier layer having a thickness between 1 and 100 nm; and
at least one organic heat seal layer made of an acrylic or methacrylic acid polymer grafted with at least one type of ionomer, the organic heat seal layer being applied in an amount between 2 and 20 g/m².

2. The multi-layer metallized paper-based packaging material according to claim 1,
wherein the metals, metalloids or a combination thereof comprised in the inorganic barrier layer are selected from the group consisting of: aluminium, aluminium oxide (AlOx), and silicon oxide (SiOx), the metals, metalloids or a combination thereof being deposited either by vacuum deposition or transfer metallization.

3. The multi-layer metallized paper-based packaging material according to claim 1, wherein the ionomer grafted to the acrylic or methacrylic polymer is a sodium ionomer.

4. The multi-layer metallized paper-based packaging material according to claim 1, wherein the acrylic or methacrylic polymer grafted with the ionomer has a molecular weight between 85 and 90 g/mol.

5. The multi-layer metallized paper-based packaging material according to claim 1, wherein each of the at least one organic barrier layer and the at least one organic heat seal layer is deposited to an adjacent layer either by aqueous dispersion, or by aqueous solution deposition.

6. The multi-layer metallized paper-based packaging material according to claim 5, wherein the at least one organic barrier layer is deposited by the aqueous solution deposition, and the at least one organic heat seal layer is deposited by aqueous dispersion coating.

7. The multi-layer metallized paper-based packaging material according to claim 1, wherein the paper layer is covered on its outer surface with an ink layer.

8. The multi-layer metallized paper-based packaging material according to claim 7, wherein the ink layer is selected from the group consisting of: water-based inks, solvent-less inks, and a combination thereof.

9. The multi-layer metallized paper-based packaging material according to claim 7, wherein the paper layer or the ink layer is covered on its outer surface by an outermost layer of an over-print varnish (OPV).

10. The multi-layer metallized paper-based packaging material according to claim 9, wherein the over-print varnish outermost layer is a styrene acrylic varnish.

11. The multi-layer metallized paper-based packaging material according to claim 1, wherein the packaging material has a Water Vapour Transmission Rate (WVTR) below 0.5 g/m²/day, measured at 23 °C, and 85% Relative Humidity, and/or an Oxygen Transmission Rate (OTR) below 0.1 cm³/m²/day bar, measured at 23 °C, and 50% Relative Humidity.

12. The multi-layer metallized paper-based packaging material according to claim 1, wherein the packaging material has a strain at break under in-plane tensile loading up to 5% in a machine direction of the paper layer and up to 15% in a cross-machine direction of the paper layer.

13. A tridimensional closed packaging item made of the multi-layer metallized paper-based packaging material according to claim 1, which is obtained by:
forming the packaging material,
filling the packaging material with an edible product for human or animal consumption, and then
sealing the packaging material.

14. A method, comprising packing the multi-layer metallized paper-based packaging material according to claim 1 with an edible product for human or animal consumption.

15. A packaged edible product, comprising the multi-layer metallized paper-based packaging material according to claim 1, filled with an edible product for food or animal consumption.
